(19) United States
(12) Patent Application Publication
(10) Pub. No.: US 2010/0141152 A1
(43) Pub. Date: Jun. 10, 2010

(54) CONTROL SYSTEM FOR CONTROLLING THE LIGHT OUTPUT OF A LED LUMINAIRE

(75) Inventors: Eduard Johannes Meijer, Eindhoven (NL); Eugene Timmering, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 11/993,269

(22) PCT Filed: Jun. 23, 2006
(86) PCT No.: PCT/IB06/52044

§ 371 Date: Dec. 20, 2007

(30) Foreign Application Priority Data
Jun. 29, 2005 (EP) 05105812.1

(51) Int. Cl. H05B 37/02; H01L 31/0232

(52) U.S. Cl. 315/149; 250/226

(57) ABSTRACT

This invention relates to a control system for controlling the light output of a LED luminaire comprising a single color LED group consisting of at least one LED. The control system comprises a spectral filter and a photodetector, which thus receives spectrally filtered light from the LED group. The photodetector generates a response signal which is applied to a control device. The control device controls the light output of said LED group at least partially on the basis of the response signal. The control system further includes an incidence angle limiting device arranged to limit the angle of incidence of the LED light received by said filter.

The present invention relates to a control system for controlling the light output of a LED luminaire comprising a single color LED group consisting of at least one LED.

The invention also relates to a photodetection device.

Luminaires having arrays of colored light-emitting diodes (LEDs), also known as RGB LED luminaires, generate various colors of light which, when properly combined, produce white light. Other colors generated by an RGB combination are also preferred in some applications, and single color luminaires are employed in other applications. RGB LED luminaires are used in, for example, LCD back-lighting, commercial-freezer lighting, and white light illumination.

Illumination by means of LED-based luminaires presents difficulties, because the optical characteristics of individual LEDs vary with temperature, forward current, and aging. In addition, the characteristics of individual LEDs that are meant to be equal vary as well. More particularly, they vary significantly from batch to batch for the same LED fabrication process and from manufacturer to manufacturer. Consequently, the quality of the light emitted from LED luminaires can vary significantly, and the desired color and the required light intensity of the light may not be obtained without a suitable light output control system.

U.S. Pat. No. 6,630,801 discloses a LED luminaire including red, green, and blue LED light sources, each consisting of a plurality of LEDs driven by an independent driver. The light emitted from each LED light source is detected by a respective filtered photodiode and an unfiltered photodiode. The response signals are correlated to chromaticity coordinates for each LED light source. Forward currents driving the respective LED light sources are adjusted in accordance with differences between the chromaticity coordinates of each LED light source and corresponding coordinates of a desired mixed color light. While compensating the varying LED properties of the LED luminaire to some extent, this method is unable to discriminate between spectral shifts, spectral broadening and intensity changes.

Improved methods solving this problem have been considered. These methods make use of narrow-band filters, preferably interference filters, such as, for example, Fabry-Perot etalons. However, while forming a basis for substantially improved solutions, the response of such a filter is undesirably spectrally broadened when the filter is illuminated by a divergent light source, such as a LED.

It is an object of the present invention to provide a control system which alleviates the above-mentioned drawback of the interference filters.

According to the present invention, this object is achieved by a control system as defined in claim 1.

In accordance with an aspect of the present invention, a control system is provided for controlling the light output of a LED luminaire comprising a single color LED group consisting of at least one LED. The control system comprises:

a spectral filter arranged to receive light emitted from the LED group;

a photodetector optically connected with said filter and arranged to detect spectrally filtered light, which has passed said filter, and generate a response signal;

a control device connected with said photodetector and arranged to control the light output of said LED group at least partially on the basis of said response signal; and

an incidence angle limiting device arranged to limit the angle of incidence of the LED light received by said filter.

The response, or transmittance, of an interference filter is dependent on the angle of incidence of the received light. This means that different wavelengths are passed for different angles of incidence on the filter. By appropriately limiting the angle of incidence, the spectrum of the filtered light is kept desirably narrow. It should be noted that the invention is not limited to interference filters, but any type of filter can be used. However, in accordance with embodiments of the present invention, as defined in claims 2 and 3, narrow-band, and in particular interference, filters are preferred, because the narrowing effect is advantageous in these filters. However, other types of filters are useful as well, such as acousto-optic tunable filters [see ref: E. G. Bucher & J. W. Carnahan, Applied Spectroscopy vol. 53, 603 (1999)], resonant grating filters [see ref: F. Lemarchand, Optics Letters, vol 23, 1149 (1998)], and photonic crystal-based filters [see ref: W. Nakagawa, Optics Letters, vol. 27, 191 (2002)].

It should also be noted that the scope of claim 1 covers one or more LED groups providing a single color or multiple colors, and one or more filters. When plural filters are used, a transparent portion is provided for each filter.

In accordance with an embodiment of the control system as defined in claim 4, an absorbent layer is provided, which has a transparent portion that is aligned with the filter. Due to the absorbent property of the layer adjacent to the transparent portion only, or at least substantially, light rays having an angle of incidence which is small enough for them to pass straight through the transparent portion reach the filter. Large-angle rays reaching the filter by reflection on walls surrounding the transparent portion are avoided.

In accordance with an embodiment of the control system as defined in claim 7, a layer structure is formed wherein the photodetector, the filter and the incidence angle limiter are stacked on each other.

These and other aspects, features, and advantages of the invention are apparent from and will be elucidated with reference to the embodiments described hereinafter.

In the drawings,

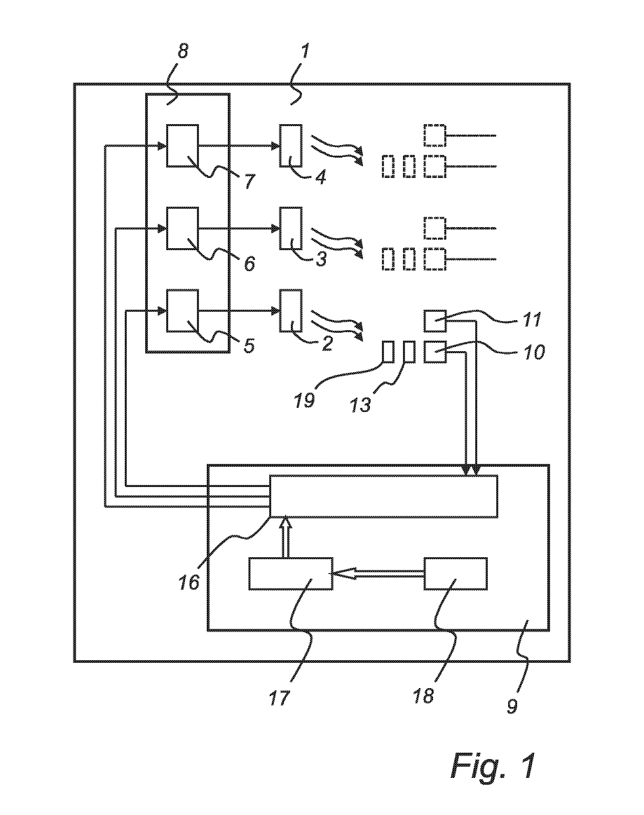

FIG. 1 is a schematic block diagram of a LED luminaire with a control system in accordance with an embodiment of the present invention;

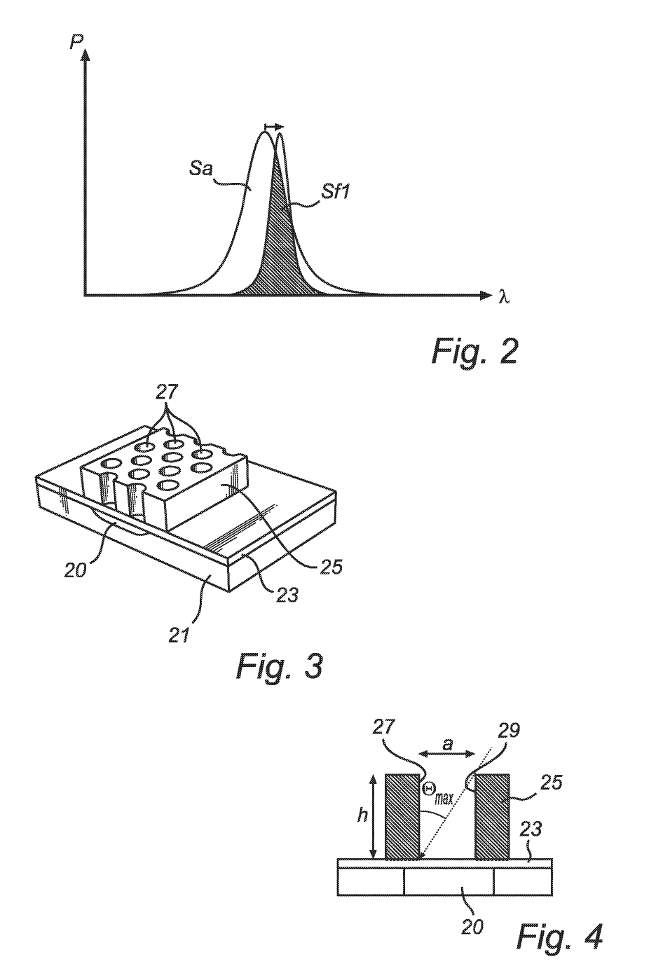

FIG. 2 schematically shows a spectral diagram illustrating a spectral situation that may occur in the LED luminaire of FIG. 1;

FIG. 3 is a schematic perspective view of a part of the control system of FIG. 1;

FIG. 4 is a schematic cross-sectional view of the part shown in FIG. 3;

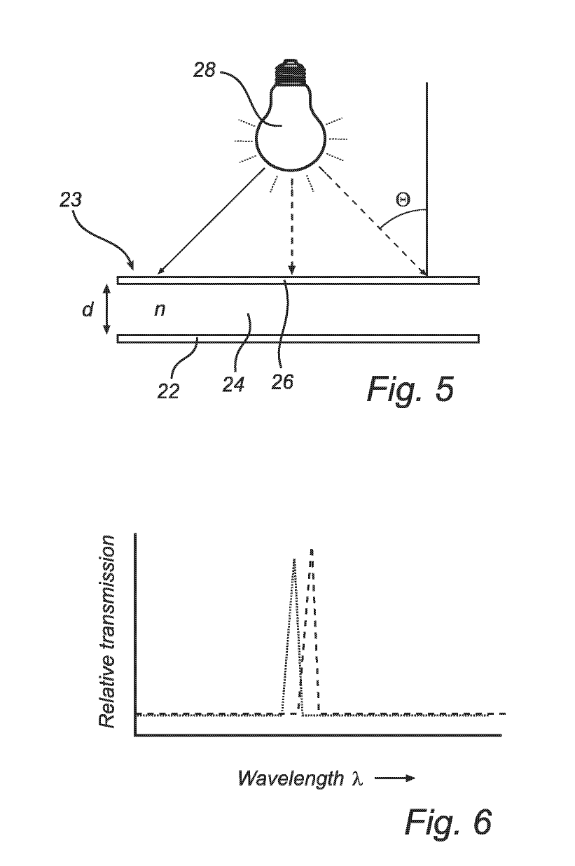

FIG. 5 schematically is a Fabry-Perot etalon filter layer, and

FIG. 6 schematically is the filter layer response.

FIG. 1 shows an RGB LED luminaire 1 as an example of an application including an embodiment of the control system according to the invention. The control system is arranged to control the output of the luminaire 1 and is integrated therein. For reasons of simplicity, a basic structure with very few elements is shown. Thus, the luminaire 1 has one red, one green, and one blue LED group, or LED light source, 2-4. Each group 2-4 consists of one LED and is driven by a respective driver 5-7 of a driver device 8. The control system consists of a control device 9, two photodetectors 10, 11 for each LED group 2-4, and a spectral filter 13 for each LED group 2-4. For two of the LED groups 2-4, the photodetectors and filters are shown in broken lines only. It is assumed that each photodetector 10, 11 is provided with the appropriate amplification and signal conversion circuitry as is commonly known in the art. The photodetectors 10, 11 are photodiodes, but may of course be other photodetection elements, such as charge-coupled devices or phototransistors.

Primarily the structure and operation of the control of the red color will now be explained. The structure and operation is similar for the other colors. Each photodetector 10, 11 has an output which is connected to a corresponding input of the control device 9. The filter 13 is a narrow-band filter, preferably a Fabry-Perot etalon, and its filter characteristic Sf1 is schematically illustrated, for example, in FIG. 2 in conjunction with a spectrum Sp of the LED. The filter 13 is arranged in front of a first photodetector 10 of the photodetectors 10, 11. An incidence angle limiter 19 is arranged in front of the filter 13. A second photodetector 11 of the photodetectors 10, 11 receives unfiltered light from the red LED 2.

The control device 9 consists of a driver controller 16, a reference generator 17 and a user input unit 18. The user input unit 18 is connected to the reference generator 17, which in turn is connected to the driver controller 16.

This control system operates as follows.

Each photodetector 10, 11 generates a response signal, the level of which is related to the amount of light that illuminates the photodetector 10, 11. The spectrally filtered photodetector 10 detects the spectrally filtered light that passes the filter 13. The control device 9 uses the response signals to control/drive the LED 2 in such a way that the spectrum and intensity of the emitted light thereof are adjusted in dependence on the response signals. In order to obtain a high control accuracy, the incidence angle limiter 19 is used to limit the angle of incidence of the light that reaches the filter 13. The angle of incidence thus limited provides a narrow filter response, which, in turn, contributes to the control accuracy. Without any limitation, several peaks may occur in the filter response, which may cause ambiguous signals fed to the control device 9. In other words, a broadened filter response would occur for a divergent beam of light illuminating the filter 13. The broadened filter response is prevented, at least to a desired extent, by means of the limiter 19. This will be further explained below.

The structure of the incidence angle limiter 19 is illustrated in FIG. 3. This Figure shows the combined structure of photodetector, filter and limiter. This combined structure can also be regarded as a separate photodetection device, but it may also constitute an integral part of the control system. The photodetector 20 is formed in a lower layer 21. The filter is provided as a mid-layer 23, deposited on the lower layer 21. The filter layer 23 is formed as a narrow-band Fabry-Perot etalon. Referring to FIG. 5, the Fabry-Perot etalon 23 consists of a bottom mirror 22, a top mirror 26, and an intermediate dielectric layer 24. The transmission of the filter 23 depends on the angle of the incident light with respect to the surface normal of the filter, which can be expressed by:

kλ=2nd cosΘ (1)

wherein k is an integer denoting the order of resonance, λ is the peak wavelength of the transmitted light, n is the refractive index of the dielectric layer 24, d is the thickness of the dielectric layer 24, and Θ is the angle of incidence. Thus, when a divergent light source 28, such as a LED, is used, the filter response is broadened in that multiple peaks occur in the passed light, as is schematically illustrated in FIG. 6.

The limiter is formed as a top layer 25 (FIG. 4) on top of the filter layer 23. The limiter 25 is formed as follows. An absorbing compound is deposited as an absorbent layer 25 on top of the mid-layer 23. After deposition of the absorbing compound, a photoresist layer is deposited on the absorbing layer 25 and a pattern is developed therein through which holes 27 are etched with an oxygen plasma through the absorbent layer 25. The etching process is stopped on the top surface of the filter layer 23 underneath, i.e. the top mirror 26 of the Fabry-Perot etalon. The holes 27 are positioned in such a way that light reaching through the holes 27 and passing through the filter layer 23 illuminates the photodetector 20. Each hole 27 constitutes a limiter element 27. The absorbing compound is chosen to be such that it absorbs all or substantially all visible light. For example, a compound known by the trade name of Darc400, which is a non-pigmented black polyimide designed for use in optoelectronic applications, or a compound PSK 1000, is suitable for the absorbent layer 25.

Consequently, a light ray that is incident at a sufficiently small angle of incidence, denoted Θₘₐₓ in FIG. 4, manages to pass through the hole 27 and reaches the underlying filter layer 23. A light ray that has a too large angle of incidence reaches the inner wall 29 of the hole 27, where it is absorbed by the absorbing compound.

The maximum angle of incidence Θₘₐₓ that is allowed for a light ray to pass the limiter 27 is determined by the ratio between the width of the transparent portion and the height of the absorbent layer 25, and more particularly Θₘₐₓ=arctan(a/h), wherein a is the diameter of the hole 27 and h is its depth. As mentioned above, the transmittance wavelengths of the Fabry-Perot etalon of the filter layer 23 are dependent on the angle of incidence Θₘₐₓ. The allowed variation of the transmitted wavelength Δλₘₐₓ, as limited by the limiter 19, can be expressed as:

$$Δ {λ}_{max} = \frac{2 nd}{k} ( 1 - cos ( {Θ}_{max} ) ) = \frac{2 nd}{k} ( 1 - cos ( arctan ( \frac{a}{h} ) ) ) \qquad ( 2 )$$

wherein k, λ, n, and d have been defined above, a is the diameter of the transparent area, which is preferably circular, and h is the height of the absorbing sidewalls of the transparent portion, such as the inner wall 29 of the hole 27. An example of a ratio a/h that prevents an undesirable broadening of the filter response is given as follows: let it be assumed that λ=400 nm. For an allowed Δλₘₐₓ of 5 nm, with k=2, holes having a height h of 8.8 μm and a diameter a of 2 μm can be used. For λ=600 nm and Δλₘₐₓ₌5 nm, with k=2, holes having a height h of 10.8 μm and a diameter a of 2 μm can be used.

An embodiment of the control system according to the present invention has been described above. This embodiment should be considered as a non-limiting example only. As will be evident to a skilled person, many modifications and alternative embodiments are possible within the scope of the invention.

It is to be noted that for the purposes of this application, and in particular with regard to the appended claims, use of the verb “comprise” and its conjugations does not exclude other elements or steps, and use of the indefinite article “a” or “an” does not exclude a plurality of elements or steps, which will be evident to a person skilled in the art.

1. A control system for controlling the light output of a LED luminaire comprising a single color LED group consisting of at least one LED, the control system comprising:
a spectral filter arranged to receive light emitted from the LED group;
a photodetector optically connected with said filter and arranged to detect spectrally filtered light, which has passed said filter, and generate a response signal;
a control device connected with said photodetector and arranged to control the light output of said LED group at least partially on the basis of said response signal; and
an incidence angle limiting device arranged to limit the angle of incidence of the LED light received by said filter.

2. A control system according to claim 1, wherein said incidence angle limiting device is a light-absorbent layer comprising a light-transparent portion aligned with said filter.

3. A control system according to claim 2, wherein said transparent portion constitutes a through-hole in said absorbent layer.

4. A control system according to claim 2, wherein the angle of incidence is dependent on a ratio between a thickness of the absorbent layer and a width of the transparent portion.

5. A control system according to claim 1, wherein said filter is an interference filter.

6. A control system according to claim 1, wherein said filter is a narrow-band filter.

7. A control system according to claim 1, wherein said photodetector, said filter and said incidence angle limiting device are deposited on top of each other on a substrate.

8. A photodetection device comprising:
a spectral filter arranged to spectrally filter light;
a photodetector optically connected with said filter and arranged to detect the spectrally filtered light, which has passed said filter, and generate a response signal;
an incidence angle limiting device arranged to limit the angle of incidence of the light received by said filter.

9. A photodetection device according to claim 8, wherein said incidence angle limiting device is a light-absorbent layer comprising a light-transparent portion aligned with said filter.

10. A photodetection device according to claim 8, wherein said transparent portion constitutes a through-hole in said absorbent layer.
